(19) United States
(12) Patent Application Publication
(10) Pub. No.: US 2013/0334531 A1
(43) Pub. Date: Dec. 19, 2013

(54) SYSTEMS AND METHODS FOR MEASURING TEMPERATURE AND CURRENT IN INTEGRATED CIRCUIT DEVICES

(71) Applicant: Franz Jost, Stuttgart (DE)

(72) Inventor: Franz Jost, Stuttgart (DE)

(21) Appl. No.: 13/524,437

(22) Filed: Jun. 15, 2012

(51) Int. Cl. H01L 23/58; H01L 21/66

(52) U.S. Cl. 257/48; 438/17; 257/E21.521; 257/E23.01

(57) ABSTRACT

Embodiments relate to measurement of temperature and current in semiconductor devices. In particular, embodiments relate to monolithic semiconductor, such as power semiconductor, and sensor, such as a current or temperature sensor, device. In embodiments, temperature and/or current sensing features are monolithically integrated within semiconductor devices. These embodiments thereby can provide direct measurement of temperature and current, in contrast with conventional solutions that provide temperature and current sensing near or alongside but not integrated within the actual semiconductor device. For example, in one embodiment an additional layer structure is applied to a power semiconductor stack in backend processing. This monolithic integration provides for localized measurement of temperature and/or current, an advantage over conventional side-by-side configurations.

### TECHNICAL FIELD

The invention relates generally to integrated circuits and more particularly to measuring current and temperature in integrated circuit devices.

BACKGROUND

Power semiconductor devices, such as power diodes, IGBTs (insulated gate bipolar transistors) and PowerMOSFETs (metal-oxide-semiconductor field-effect transistors) used for switching or other applications, can experience high currents and temperatures during operation. Both current and temperature typically are measured or monitored in power devices. For example, high currents can lead to heat dissipation issues, and high temperatures related thereto can lead to device malfunction, damage, destruction or reduced lifetime.

Conventional approaches for measuring and monitoring current and temperature include integrating devices, such as diodes or other circuitry, with the power device. Because of technological process variations as well as nonlinear and non-reproducible characteristics of the semiconductor devices, however, these approaches are not very accurate, varying by +/−15 degrees C. or more for temperature and +/−5 A or more current. Moreover, temperature measuring devices typically require additional calibration and therefore memory, as the temperature sensing device senses the temperature where it is positioned within the power device module relative to the power device itself, and this may not accurately reflect the temperature the device or a portion thereof is experiencing.

Therefore, there is a need for improved devices, systems and methods for sensing current and temperature in power and other semiconductor devices.

### SUMMARY

Embodiments relate to monolithic semiconductor, such as power semiconductor, and sensor, such as a current or temperature sensor, device.

In an embodiment, a monolithic semiconductor device comprises a semiconductor device portion; and a sensor portion monolithically formed with the semiconductor device portion and configured to sense at least one characteristic of the semiconductor device portion.

In an embodiment, a semiconductor device comprises a semiconductor device portion; a sensing portion configured to sense at least one of a temperature or a current of the semiconductor device portion; and an isolation layer coupled between the semiconductor device portion and the sensing portion such that the semiconductor device portion, the isolation layer and the sensing portion form a monolithic semiconductor device.

In an embodiment, a method comprises forming a semiconductor device; forming a sensor device to sense at least one characteristic of the semiconductor device; and forming an isolation layer to couple the semiconductor device and the sensor device to form a monolithic structure.

In an embodiment, a method comprises providing a monolithic power semiconductor and sensing device; and sensing a characteristic of the power semiconductor device by the sensing device.

### BRIEF DESCRIPTION OF THE DRAWINGS

The invention may be more completely understood in consideration of the following detailed description of various embodiments of the invention in connection with the accompanying drawings, in which:

FIG. 1 is a block diagram of a monolithic semiconductor and sensor device according to an embodiment.

FIG. 2 is a circuit diagram according to an embodiment.

FIG. 3A is a circuit diagram according to an embodiment.

FIG. 3B is a circuit diagram according to an embodiment.

FIG. 4A is a circuit diagram according to an embodiment.

FIG. 4B is a circuit diagram according to an embodiment.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

Embodiments relate to measurement of temperature and current in semiconductor devices. In particular, embodiments relate to monolithic semiconductor, such as power semiconductor, and sensor, such as a current or temperature sensor, device. In embodiments, temperature and/or current sensing features are monolithically integrated within semiconductor devices. These embodiments thereby can provide direct measurement of temperature and current, in contrast with conventional solutions that provide temperature and current sensing near or alongside but not integrated within the actual semiconductor device. For example, in one embodiment an additional layer structure is applied to a power semiconductor stack in backend processing. This monolithic integration provides for localized measurement of temperature and/or current, an advantage over conventional side-by-side configurations.

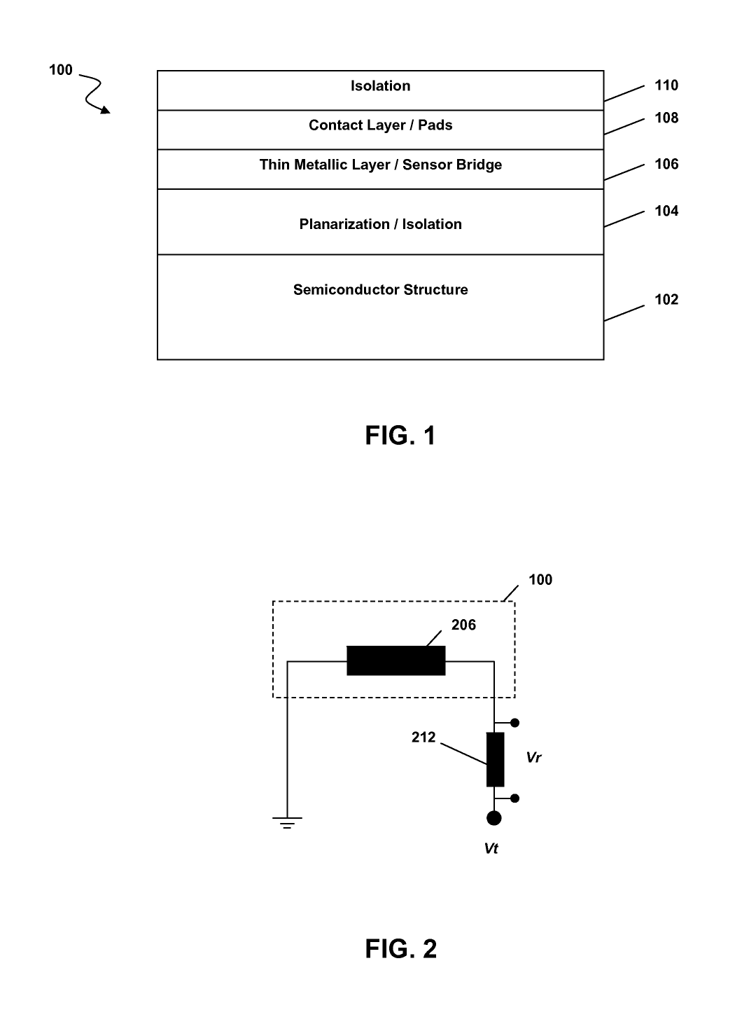

Referring to FIG. 1, a monolithic semiconductor stack arrangement 100 is depicted. Stack 100 comprises a semiconductor structure 102, such as a power semiconductor device or other semiconductor device. While depicted as a single layer, semiconductor structure 102 can comprise a plurality of layers and/or elements which form the structure of the particular semiconductor device. For example, semiconductor structure 100 can comprise a power MOSFET, an IGBT or some other semiconductor device. The particular device of structure 102 is not limiting to the invention, and the concept of integrating the temperature and/or current sensing structure and functionality within the device can be applicable to a wide range of semiconductor devices. Power semiconductor devices will be used herein throughout as examples given the particular issues with respect to current and temperature that affect those devices, but these examples are in no way to be considered limiting with respect to embodiments of the invention generally.

Planaraization and/or isolation structure 104 is formed on semiconductor structure 102 in embodiments. Structure 104, like structure 102, can comprise a plurality of individual layers and/or elements in embodiments and functions primarily to isolate semiconductor structure 102 from other portions of stack 100. In embodiments, structure 104 comprises an isolation layer.

In embodiments, layers 106-110 form a sensor device monolithic with semiconductor device 102 and isolation structure 104. In one embodiment, the sensor device comprises a thin metallic layer 106 coupled to isolation structure 104. In embodiments, layer 106 is used for monolithic integrated temperature and/or current sensing of semiconductor structure 102 and comprises a sensor bridge configuration or other structure suitable for sensing temperature and/or current in stack 100. Layer 106 can be, for example, about 1 nanometer (nm) thick to about 1000 nm thick in embodiments. In anisotropic magnetoresistive (AMR) embodiment discussed herein below, the AMR elements are about 20 nm to about 30 nm thick in embodiments, though this can vary and be thinner or thicker in other embodiments.

In embodiments, materials are selected to allow for small thicknesses, small sensing area footprint and low crosstalk to mechanical stress. In embodiments, layer 106 can comprise platinum, nickel iron, nickel or other suitable metals or alloys. Layer 106 can be added to stack 100 in backend or other processing with standard thin film processing on wafer level, such as deposition and structuring, to produce an integrated device. It is also possible to start with the sensor layer structure and then to process the power device, or to intermix the two processes or use other suitable processes as appreciated by those skilled in the art. In other embodiments, layer 106 can comprise a magnetic thin film, such as a magnetoresistive (xMR) layer. For example, layer 106 can comprise an anisotropic magnetoresitive (AMR) layer such as nickel iron, a giant magnetoresistive (GMR), a tunneling magnetoresistive (TMR) layer or some other suitable material. For example, an AMR element can comprise about 80% nickel and about 20% iron in one embodiment. As in other embodiments, these materials or structures can be added to stack 100 in backend processing. In embodiments, only temperature can be needed or desired to be measured, in which case the magnetic contribution to the resistance change can be eliminated using a dedicated design or annealing process step.

Stack 100 also comprises a contact layer and/or bond pads 108 formed on layer 106, which is used with layer 106 for measuring the temperature and/or current in stack 100. In embodiments, layer 108 comprises aluminum, copper or some other suitable material or alloy. An isolation layer 110 is formed on layer 108. In embodiments, layer 110 comprises silicon dioxide (SiO2), silicon nitride (SiN4) or some other suitable material or alloy.

In other embodiments, layers 104-110 can be formed under or within device 102. In other words, device 102 can be formed on the bottom, the top or, in other embodiments, in between.

In operation, and referring to FIG. 2, the resistance of layer 106 changes with temperature in a linear manner such that the temperature within stack 100 and of semiconductor device 102 can be precisely measured. In FIG. 2, the resistance of layer 106 is modeled as resistor 206, and a measurement resistor 212 external to stack 100 can be used to measure that resistance by determining a voltage drop, Vr, across resistor 212. In other embodiments, a current drop can be used. Because the resistance of layer 106 (resistor 206) changes with changes in temperature, the temperature can be measured directly within stack 100. For example, the resistance of layer 106 (resistor 206) increases as temperature increases such that if resistance increases by 30% for each 100 degree C. change in temperature, the resistance of layer 106 (resistor 206) would change from 1k Ohms at 0 degrees C. to 1.3k Ohms at 100 degrees C. Because the resistance is very linear, the temperature of stack 100 can easily determined from the measured change in resistance.

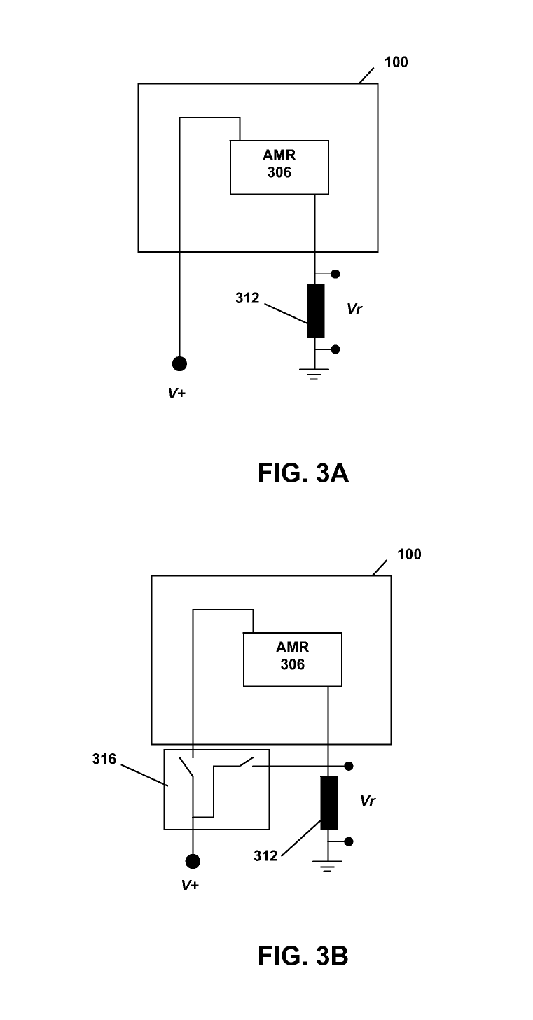

In another embodiment in which layer 106 comprises xMR elements, such as AMR elements, temperature can be measured using the AMR resistors. Referring to FIG. 3A, and similarly to the embodiment of FIG. 2, an external resistor 312 can be coupled to an AMR element 306 of layer 106. A constant voltage V+ can be input to AMR element 306 such that the voltage drop across resistor 312 can be measured to determine the temperature from a change in resistance.

Voltage V+, however, can itself cause a temperature change that affects device 100. Therefore, in the embodiment of FIG. 3B, voltage V+ can be multiplexed with resistor 306 by multiplexer 316. Then, to determine the temperature independent of voltage V+, the two voltage drops across resistor 312, with voltage V+ multiplexed directly to resistor 312 and with it not, can be measured and a ratio between the two values determined to measure the temperature independently of the affects of voltage V+. This can provide, for certain applications in which it is desired, a higher degree of accuracy. In other embodiments, a constant current, rather than a constant voltage, can be provided.

Simulated test results of embodiments discussed herein show that the accuracy of embodiments is within about +/−4 degrees C. in a temperature range of about −40 degrees to about 160 degrees C. This is an improvement over conventional approaches. Moreover, this improvement is realized by embodiments which are monolithically integrated within stack 100 without affecting the thermal or operational characteristics of stack 100. Additional advantages of a simplified structure, smaller device footprint and others are therefore realized in addition to the aforementioned improved temperature accuracy.

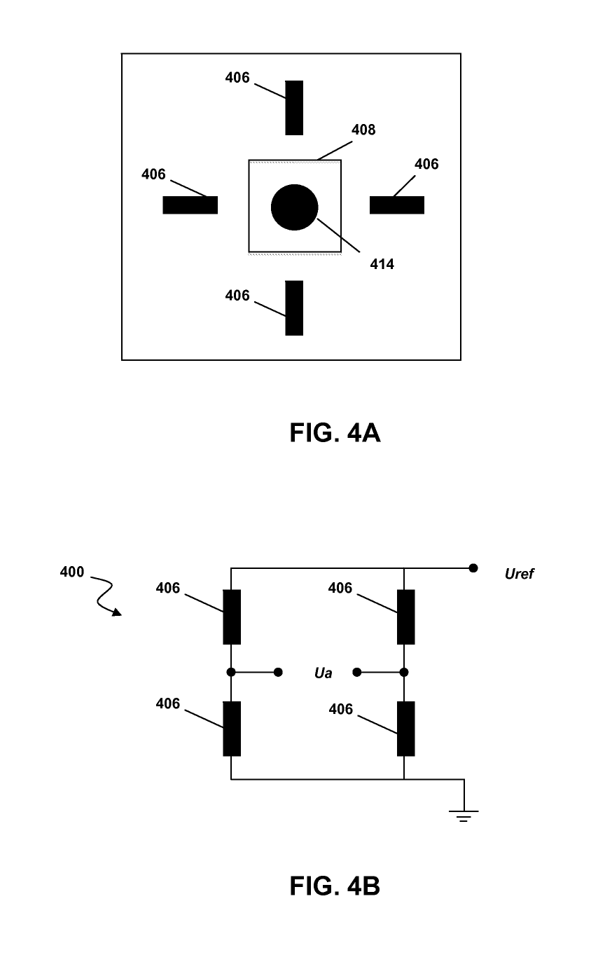

To measure current, and referring to FIG. 4, a sensor bridge comprising a plurality of resistors 406 can be formed around a bond pad 408 of layer 108 to measure current via a magnetic field induced by that current. If the power device comprises a plurality of pads 408 in which current is flowing, the individual currents can be measured, and those currents can be evaluated singly or summed in embodiments. A magnetic field can be generated by, for example, a bond wire 414 carrying current, and the magnetic field changes the resistance in the sensors 406 coupled in a bridge (refer to FIG. 4B) such that the current U can be measured.

Referring to FIG. 4B, resistors 406 can comprise xMR elements in embodiments, such as GMR or AMR elements, coupled in a bridge 400. XMR elements 406 comprise meanders in embodiments, and in one configuration the current in bond wire 414 changes the resistance of two of the resistors 406, e.g., the top and bottom resistors, but not those of the other two resistors 406, e.g., on the left and right as depicted on the page of FIG. 4.

Thus, the output of sensor bridge 406, U, is directly proportional to the current flowing in the device such that the current can be measured. For example, in one embodiment Ua is equal to the current, I, times the change in resistance. If the change is resistance related to the magnetic field induced by the current is about 2% (e.g., about 980 Ohms to about 1.2k Ohms) and Ua is measured, the current can be determined from that change and the measured Ua. Bridge 400 is driven at a constant voltage or current, such as Uref=about 5 mA in an embodiment. In another embodiment, Vref is about 5V. In embodiments, bridge 400 also can be used to measure temperature as discussed herein above.

Applications of embodiments can vary. For example, in an IGBT switching device, it can be desirable to measure the current during an on-off phase. In operation, current measurement in such a device can be synchronized in order to collect data during that particular phase while avoiding artifacts from other parts of the circuit. Other approaches can be taken in other particular implementations of embodiments, whether for temperature, current or both, as appreciated by those skilled in the art.

Embodiments thereby provide for localized measurement of temperature and/or current by a monolithic power and sensor device, providing advantages over conventional side-by-side configurations. In embodiments, the sensor device, alone or in combination with a microcontroller or other suitable device coupled thereto, can be used provide information related to or comprising an instantaneous current value, a maximum current value and/or a variation over time of the current. This information can be used to determine current status information related to the power device as well as to predict an operational lifetime, likelihood of breakdown or malfunction, or some other longer-term characteristic of the power device.

Various embodiments of systems, devices and methods have been described herein. These embodiments are given only by way of example and are not intended to limit the scope of the invention. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the invention.

Persons of ordinary skill in the relevant arts will recognize that the invention may comprise fewer features than illustrated in any individual embodiment described above. The embodiments described herein are not meant to be an exhaustive presentation of the ways in which the various features of the invention may be combined. Accordingly, the embodiments are not mutually exclusive combinations of features; rather, the invention can comprise a combination of different individual features selected from different individual embodiments, as understood by persons of ordinary skill in the art. Moreover, elements described with respect to one embodiment can be implemented in other embodiments even when not described in such embodiments unless otherwise noted. Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended. Furthermore, it is intended also to include features of a claim in any other independent claim even if this claim is not directly made dependent to the independent claim.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims for the present invention, it is expressly intended that the provisions of Section 112, sixth paragraph of 35 U.S.C. are not to be invoked unless the specific terms “means for” or “step for” are recited in a claim.

1. A monolithic semiconductor device comprising:
a semiconductor device portion; and
a sensor portion monolithically formed with the semiconductor device portion and configured to sense at least one characteristic of the semiconductor device portion.

2. The device of claim 1, wherein the semiconductor device portion comprises a power semiconductor device portion.

3. The device of claim 2, wherein the power semiconductor device portion comprises one of an insulated gate bipolar transistor (IGBT) or a power metal-oxide-semiconductor field-effect transistor (MOSFET).

4. The device of claim 2, wherein the at least one characteristic comprises a temperature or a current.

5. The device of claim 1, wherein the sensor portion is monolithically formed with the semiconductor device portion in as backend manufacturing process.

6. The device of claim 1, wherein the sensor portion comprises a thin metallic layer.

7. The device of claim 6, herein the thin metallic layer comprises at least one of platinum nickel iron, nickel, or magnetoresistive (xMR) material.

8. The device of claim 7 wherein the thin metallic layer comprises an xMR sensor bridge.

9. The device of claim 6, further comprising an external resistor element coupled to the thin metallic layer, wherein the sensor portion is configured to sense the at least one characteristic by measuring one of a current drop or a voltage drop across the external resistor element.

10. The device of claim 6, wherein the sensor portion further comprises a contact layer and an isolation layer.

11. The device of claim 1 wherein the sensor portion is coupled to the semiconductor device portion by an isolation layer.

12. A semiconductor device comprising
a semiconductor device portion;
sensing portion configured to sense at least one of a temperature or a current of the semiconductor device portion; and
an isolation layer coupled between the semiconductor device portion and the sensing portion such that the semiconductor device portion, the isolation layer and the sensing portion form a monolithic semiconductor device.

13. The device of claim 12, wherein the semiconductor device portion comprises a power semiconductor device.

14. The device of claim 13, wherein the power semiconductor device comprises one of an insulated gate bipolar transistor (IGBT) or a power metal-oxide-semiconductor field-effect transistor (MOSFET).

15. The device of claim 12, wherein the sensing portion comprises to sensor layer and a contact layer.

16. The device of claim. 12, wherein the sensing portion comprises a sensor bridge.

17. A method comprising:
forming a semiconductor device;
forming a sensor device to sense at least one characteristic of the semiconductor device; and
forming, an isolation layer to couple the semiconductor device and the sensor device to form a monolithic structure.

18. The method of claim 17, wherein forming a semiconductor device comprises forming a power semiconductor device.

19. The method of claim 18, wherein forming a power semiconductor device comprises forming a switching device.

20. The method of claim 17, further comprising sensing a current flowing in the semiconductor device by the sensor device.

21. The method of claim 17, further comprising, sensing a temperature of the semiconductor device by the sensor device.

22. The method of claim 21, further comprising:
sensing a current flowing in the semiconductor device and the temperature of the semiconductor device by the sensor device;
determining at least one of an instantaneous current value, a maximum current value or a variation over time of the current from the sensing; and
using a result of the determining to predict an operational lifetime of the semiconductor device.

23. The method of claim 17, wherein forming the sensor device comprises forming a sensor bridge.

24. The method of claim 23, wherein forming a sensor bridge comprises forming at least one magnetoresistive element coupled in the sensor bridge.

25. The method of claim 23, further comprising coupling a resistor to the sensor bridge; and measuring a voltage or current drop across the resistor to sense the at least one characteristic of the semiconductor device.

26. The method of claim 25, further comprising multiplexing the resistor to a voltage or current source.

27. The method of claim 26, further comprising measuring the voltage or current drop across the resistor with the resistor multiplexed to the voltage or current source and without the resistor multiplexed to the voltage or current source; and determining a ratio of the measuring.

28. To A method comprising:
providing a monolithic power semiconductor and sensing device; and
sensing a characteristic of the power semiconductor device by the sensing device.

29. The method of claim 28, wherein the characteristic comprises at least one of a temperature or a current.

30. The method of claim 28, wherein the sensing device comprises a thin film sensing device.
